(19) United States
(12) Patent Application Publication
(10) Pub. No.: US 2020/0258718 A1
(43) Pub. Date: Aug. 13, 2020

(54) Gas Supply With Angled Injectors In Plasma Processing Apparatus

(71) Applicants: Mattson Technology, Inc., Fremont, CA (US); Beijing E-Town Semiconductor Technology, Co., LTD, Beijing (CN)

(72) Inventors: Tinghao F. Wang, Fremont, CA (US); Yorkman Ma, San Jose, CA (US); Yun Yang, Berwyn, PA (US); Shawming Ma, Sunnyvale, CA (US); Moo-Hyun Kim, Dublin, CA (US); Peter J. Lembesis, Boulder Creek, CA (US); Ryan M. Pakulski, Brentwood, CA (US)

(21) Appl. No.: 16/270,063

(22) Filed: Feb. 7, 2019

(51) Int. Cl. H01J 37/32; H01L 21/67

(52) U.S. Cl. CPC H01J 37/3244; H01L 21/67069; H01J 2237/006; H01J 37/321; H01J 37/32715

(57) ABSTRACT

Plasma processing apparatus and associated methods are provided. In one example implementation, the plasma processing apparatus can include a gas supply in a processing chamber of a plasma processing apparatus, such as an inductively coupled plasma processing apparatus. The gas supply can include one or more injectors. Each of the one or more injectors can be angled relative to a direction parallel to a radius of the workpiece to produce a rotational gas flow relative to a direction perpendicular to a center of the workpiece. Such gas supply can improve process uniformity, workpiece edge critical dimension tuning, gas ionization efficiency, and/or symmetric flow inside the processing chamber to reduce particle deposition on a workpiece and can also reduce heat localization from a stagnate flow.

### FIELD

The present disclosure relates generally to gas supply for plasma processing apparatus and systems.

### BACKGROUND

Plasma processing tools can be used in the manufacture of devices such as integrated circuits, micromechanical devices, flat panel displays, and other devices. Plasma processing tools used in modern plasma etch and/or strip applications are required to provide a high plasma uniformity and a plurality of plasma controls, including independent plasma profile, plasma density, and ion energy controls. Plasma processing tools can, in some instances, be required to provide a good and uniform coverage against a wafer and a good control of wafer edge critical dimension tuning.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus. The plasma processing apparatus can include a processing chamber having a workpiece support. The workpiece support can support a workpiece during plasma processing. The plasma processing apparatus can include an inductively coupled plasma source to induce a plasma in a process gas in the processing chamber. The plasma processing apparatus can include a gas supply to deliver the process gas to the processing chamber. The gas supply can include one or more injectors. Each of the one or more injectors can be angled relative to a direction parallel to a radius of the workpiece to produce a rotational gas flow relative to a direction perpendicular to a center of the workpiece.

Another example aspect of the present disclosure is directed to a method of processing a workpiece. The method can include placing the workpiece on a workpiece support in a processing chamber. The method can include admitting, via a gas supply, a process gas into the processing chamber. The method can include generating a plasma in the process gas in the processing chamber. The method can include exposing the workpiece to one or more species generated by the plasma. The gas supply can include one or more injectors. Each injector of the one or more injectors can be angled relative to a direction parallel to a radius of the workpiece to produce a rotational gas flow relative to a direction perpendicular to a center of the workpiece.

Variations and modifications can be made to example embodiments of the present disclosure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts an example gas supply according to example embodiments of the present disclosure;

FIG. 3 depicts an example gas supply according to example embodiments of the present disclosure;

FIG. 4 depicts an example plasma processing apparatus according to example embodiments of the present disclosure;

FIG. 5 depicts an example gas supply according to example embodiments of the present disclosure;

FIG. 6 depicts an example cross-section view of edge gas injectors according to example embodiments of the present disclosure;

FIG. 7 depicts an example cross-section view of edge gas injectors according to example embodiments of the present disclosure;

FIG. 8 depicts an example plasma processing apparatus according to example embodiments of the present disclosure;

FIG. 9 depicts a flow diagram of an example method according to example embodiments of the present disclosure;

FIG. 10 depicts an example gas velocity comparison between a gas supply and an example gas supply according to example embodiments of the present disclosure;

FIG. 11 depicts an example mass fraction comparison between a gas supply and an example gas supply according to example embodiments of the present disclosure; and

FIG. 12 depicts an example comparison of gas mass fraction on workpiece surface distribution between a gas supply and an example gas supply according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to a plasma processing apparatus and associated methods. The plasma processing apparatus can include a gas supply in a processing chamber of a plasma processing apparatus, such as an inductively coupled plasma processing apparatus. The gas supply can include one or more injectors (e.g., gas nozzles). Each of the one or more injectors can be angled relative to a direction parallel to a radius of the workpiece to produce a rotational gas flow relative to a direction perpendicular to a center of the workpiece. Since the injectors of the gas supply are not normal to an edge of the workpiece and the injectors are not arranged in a symmetric gas injection pattern, such gas supply can improve process uniformity (e.g., across-workpiece uniformity, azimuthal etch uniformity at an edge of a workpiece, etchant mass fraction uniformity at a surface of a workpiece, and/or a flow velocity uniformity at a surface of a workpiece), workpiece edge critical dimension tuning, gas ionization efficiency, and/or symmetric flow inside the processing chamber to reduce particle deposition on a workpiece and can also reduce heat localization from a stagnate flow.

According to example aspects of the present disclosure, the gas supply can be integrated with a side wall of the plasma processing chamber. The gas supply can have injectors arranged in an azimuthal symmetry gas injection pattern for workpiece edge critical dimension and/or uniformity tuning. In some embodiments, the gas supply can include one or more gas manifolds. Each gas manifold can be integrated with the plasma processing chamber shields and/or liners. Each gas manifold can be parallel with a workpiece plane. Distances between a gas manifold and a workpiece plane can be determined through calculations and/or various process test results. Each gas manifold can include one or more gas injectors to deliver a gas flow around or toward a periphery of a workpiece. Each of the injectors in each gas manifold can be angled relative to a direction parallel to a radius of the workpiece to produce a rotational gas flow relative to a direction perpendicular to a center of the workpiece. As one example, the injectors can be angled in a clockwise or counter-clockwise direction to produce a clockwise or counter-clockwise gas flow relative to a direction perpendicular to a center of a workpiece. An angle between each injector and the direction parallel to the radius of the workpiece can be no more than about 60 degrees, such as between about 15 degrees and 45 degrees. In some embodiments, at least one injector of a gas manifold can be angled upward or downward to a workpiece. In some embodiments, the injectors of a gas manifold can be in a diagonal direction toward to the workpiece plane.

In some embodiments, a plasma processing chamber liner can have one gas manifold. The gas manifold can include a set of injectors (e.g., about 4 to about 30 individual injectors). The injectors can be arranged to aim at an edge of a workpiece and can be angled relative to a direction parallel to a radius of the workpiece. The injectors can also be in an angle downward with a workpiece plane to produce a rotational gas flow relative to a direction perpendicular to a center of the workpiece. This can become a way to adjust or fine tune a gas flow concentration near the workpiece edge. It can also change chamber flow conditions in combination with top gas flow and edge gas flow injections.

In some embodiments, at least an inlet port can be used for a circular gas manifold. For instance, two inlets can be used to flow a gas into the gas manifold. The two inlet ports can be configured close each other so that a small size of tee adapter/fitting can be used to deliver the gas from a single delivery line. Inside the gas manifold, gas particles from each inlet port can be collided or pushed away from each other. As a result, the two-port design can provide a better gas distribution for the injectors than a single gas port design.

According to example aspects of the present disclosure, the gas supply can be located in a ceiling of the plasma processing chamber (e.g., on a top dome of the processing chamber). The injectors can be located at a center and/or one or more edges of the gas supply. The injectors can be arranged in an azimuthal symmetric gas injection pattern relative to a direction perpendicular to a center of a workpiece. For instance, each of the injectors can be angled relative to a direction parallel to a radius of the workpiece to produce a rotational gas flow relative to the direction perpendicular to the center of the workpiece. As one example, the injectors can be angled in a clockwise or counter-clockwise direction to produce a clockwise or counter-clockwise gas flow relative to the direction perpendicular to the center of the workpiece. An angle between each injector and the direction parallel to the radius of the workpiece can be no more than about 60 degrees, such as between about 15 degrees and 45 degrees. In some embodiments, at least one injector can be angled upward or downward to a workpiece.

One example aspect of the present disclosure is directed to a plasma processing apparatus. The processing chamber can include a workpiece support to support a workpiece during plasma processing. The processing chamber can include an inductively coupled plasma source to induce a plasma in a process gas in the processing chamber. The processing chamber can include a gas supply to deliver the process gas to the processing chamber. The gas supply can include one or more injectors. Each of the one or more injectors can be angled relative to a direction parallel to a radius of the workpiece to produce a rotational gas flow relative to a direction perpendicular to a center of the workpiece.

In some embodiments, the gas supply can be integrated with a side wall of the processing chamber. In some embodiments, the gas supply can include at least one gas manifold, the at least one gas manifold can include the one or more injectors. In some embodiments, at least one injector can deliver the process gas at a downstream location from the inductively coupled plasma source. In some embodiments, the injectors can be angled in a clockwise or counter-clockwise direction to produce a clockwise or counter-clockwise gas flow relative to the direction perpendicular to the center of the workpiece. An angle between each injector and the direction parallel to the radius of the workpiece can be no more than about 60 degrees, such as between about 15 degrees and about 45 degrees. In some embodiments, at least one injector can be angled upward or downward to a workpiece.

One example aspect of the present disclosure is directed to a method of processing a workpiece. The method can include placing the workpiece on a workpiece support in a processing chamber. The method can include admitting, via a gas supply, a process gas into the processing chamber. The method can include generating a plasma in the process gas in the processing chamber. The method can include exposing the workpiece to one or more species generated by the plasma. The gas supply can include one or more injectors. Each injector of the one or more injectors can be angled relative to a direction parallel to a radius of the workpiece to produce a rotational gas flow relative to a direction perpendicular to a center of the workpiece.

Example aspects of the present disclosure can provide a number of technical effects and benefits. For instance, injectors of a gas supply in a plasma processing can be angled relative to a direction parallel to a radius of a workpiece to produce a rotational gas flow relative to a direction perpendicular to a center of the workpiece. As such, such gas supply can improve etch amount and critical dimension azimuthal symmetry with wider process window. The gas supply can also improve workpiece edge critical dimension tunability, across-workpiece uniformity, and chamber wall plasma dry cleaning efficiency. The gas can also reduce particle deposition on workpiece and gas purge time during workpiece transfer or step transition.

Example aspects of the present disclosure are discussed with reference to inductive plasma source for purposes of illustration and discussion. Those of ordinary skill in the art, using the disclosures provided herein, will understand that other plasma sources can be used without deviating from the scope of the present disclosure. For instance, a plasma processing apparatus can include an inductively coupled plasma source with an electrostatic shield. The plasma processing apparatus can include an inductively coupled plasma source without an electrostatic shield. The plasma processing apparatus can include a capacitively coupled plasma source (e.g., using a bias disposed, for instance, in a pedestal or workpiece support).

Aspects of the present disclosure are discussed with reference to a “workpiece” that is a “semiconductor wafer” for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within ten percent (10%) of the stated numerical value. A “pedestal” refers to any structure that can be used to support a workpiece.

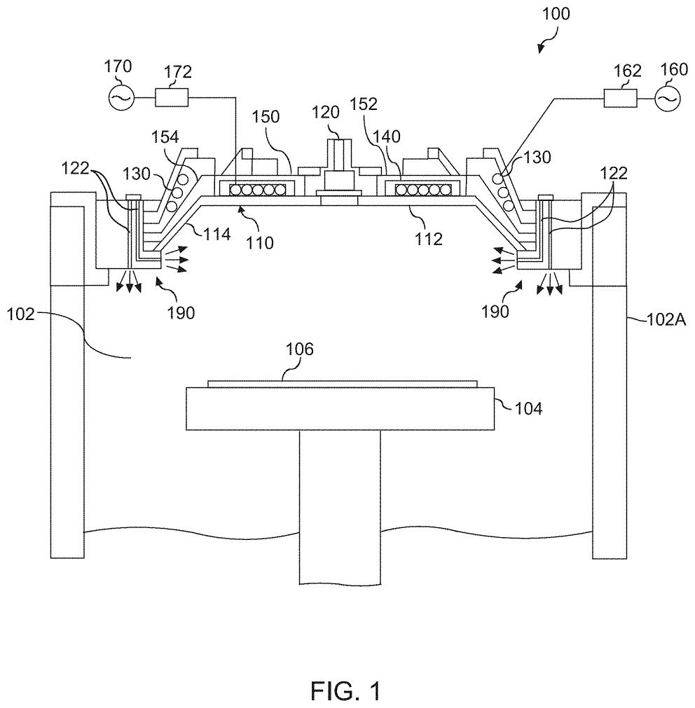

FIG. 1 depicts an example plasma processing apparatus 100 according to example embodiments of the present disclosure. The plasma processing apparatus 100 includes a processing chamber defining an interior space 102. A pedestal or workpiece holder 104 is used to support a workpiece 106, such as a semiconductor wafer, within the interior space 102. A dielectric window 110 is located above the workpiece holder 104. The dielectric window 110 includes a relatively flat central portion 112 and an angled peripheral portion 114. The dielectric window 110 includes a space in the central portion 112 for a showerhead 120 to feed process gas into the interior space 102.

The apparatus 100 further includes a plurality of inductive elements, such as primary inductive element 130 and secondary inductive element 140, for generating an inductive plasma in the interior space 102. The inductive elements 130, 140 can include a coil or antenna element that when supplied with RF power, induces a plasma in the process gas in the interior space 102 of plasma processing apparatus 100. For instance, a first RF generator 160 can be configured to provide electromagnetic energy through a matching network 162 to the primary inductive element 130. A second RF generator 170 can be configured to provide electromagnetic energy through a matching network 172 to the secondary inductive element 140.

While the present disclosure makes reference to a primary inductive, and a secondary inductive, those of ordinary skill in the art, should appreciate that the terms primary and secondary are used for convenience purposes only. The secondary coil can be operated independent of the primary coil, and vice versa.

While the present disclosure makes reference to a primary inductive, and a secondary inductive, those of ordinary skill in the art, should understand that an apparatus does not need include all of them. The apparatus can include one or more (e.g., one or two) of the primary inductive element and the secondary inductive element.

The apparatus 100 can include a metal shield portion 152 disposed around the secondary inductive element 140. The metal shield portion 152 separates the primary inductive element 130 and the secondary inductive element 140 to reduce cross-talk between the inductive elements 130, 140. The apparatus 100 can further include a Faraday shield 154 disposed between the primary inductive element 130 and the dielectric window 130. Faraday shield 154 can be a slotted metal shield that reduces capacitive coupling between the primary inductive element 154 and the processing chamber 102. As illustrated, Faraday shield 154 can fit over the angled portion of the dielectric shield 110.

In a particular embodiment, metal shield 152 and Faraday shield 154 can form a unitary body 150 for ease of manufacturing and other purposes. The multi-turn coil of the primary inductive element 130 can be located adjacent the Faraday shield portion 154 of the unitary body metal shield/Faraday shield 150. The secondary inductive element 140 can be located proximate the metal shield portion 152 of metal shield/Faraday shield unitary body 150, such as between the metal shield portion 152 and the dielectric window 110.

The arrangement of the primary inductive element 130 and the secondary inductive element 140 on opposite sides of the metal shield 152 allows the primary inductive element 130 and secondary inductive element 140 to have distinct structural configurations and to perform different functions. For instance, the primary inductive element 130 can include a multi-turn coil located adjacent a peripheral portion of the process chamber. The primary inductive element 130 can be used for basic plasma generation and reliable start during the inherently transient ignition stage. The primary inductive element 130 can be coupled to a powerful RF generator and expensive auto-tuning matching network and can be operated at an increased RF frequency, such as at about 13.56 MHz.

The secondary inductive element 140 can be used for corrective and supportive functions and for improving the stability of the plasma during steady state operation. Since the secondary inductive element 140 can be used primarily for corrective and supportive functions and improving stability of the plasma during steady state operation, the secondary inductive element 140 does not have to be coupled to as powerful an RF generator as the first inductive element 130 and can be designed differently and cost effectively to overcome the difficulties associated with previous designs. In some instances, the secondary inductive element 140 can also be operated at a lower frequency, such as at about 2 MHz, allowing the secondary inductive element 140 to be very compact and to fit in a limited space on top of the dielectric window.

The primary inductive element 130 and the secondary inductive element 140 can be operated at different frequencies. The frequencies can be sufficiently different to reduce cross-talk between the primary inductive element 130 and the secondary inductive element 140. Due to the different frequencies that can be applied to the primary inductive element 130 and the secondary inductive element 140, there is reduced interference between the inductive elements 130, 140. More particularly, the only interaction in the plasma between the inductive elements 130, 140 is through plasma density. Accordingly, there is no need for phase synchronization between the RF generator 160 coupled to the primary inductive element 130 and the RF generator 170 coupled to the secondary inductive element 140. Power control is independent between the inductive elements. Additionally, since the inductive elements 130, 140 are operating at distinctly different frequencies, it is practical to use frequency tuning of the RF generators 160, 170 for matching the power delivery into the plasma, greatly simplifying the design and cost of any additional matching networks.

For instance (not shown in FIG. 1), the second inductive element 140 can include a planar coil and a magnetic flux concentrator. The magnetic flux concentrator can be made from a ferrite material. Use of a magnetic flux concentrator with a proper coil gives high plasma coupling and good energy transfer efficiency of the secondary inductive element 140, and significantly reduces its coupling to the metal shield 150. Use of a lower frequency, such as about 2 MHz, on the secondary inductive element 140 increases the skin layer, which also improves plasma heating efficiency.

In some embodiments, the different inductive elements 130 and 140 can carry different functions. Specifically, only the primary inductive element 130 has to carry out the most vital function of the plasma generation during ignition and providing enough priming for the secondary inductive element 140. This primary inductive element 130 can participate in the operation of the inductively coupled plasma (ICP) tool and should have coupling to both plasma and the grounded shield to stabilize plasma potential. The Faraday shield 154 associated with the first inductive element 130 can avoid window sputtering and can be used to supply the coupling to the ground.

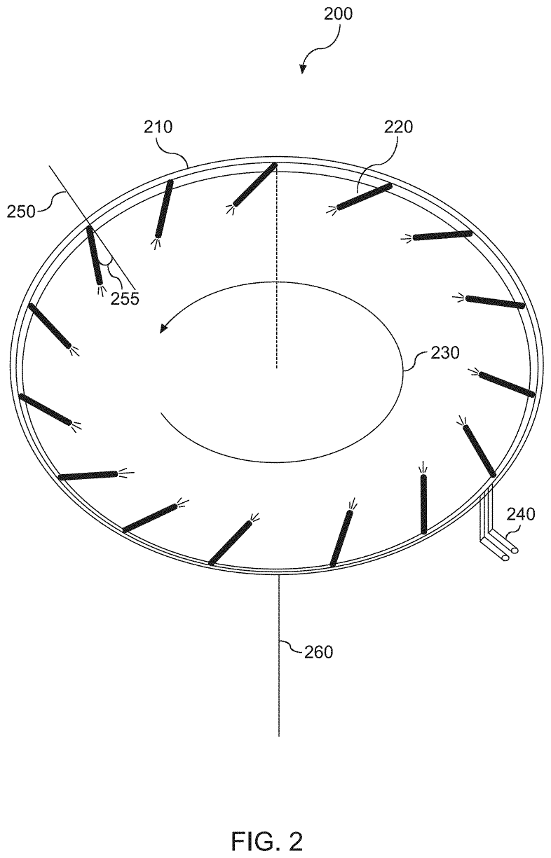

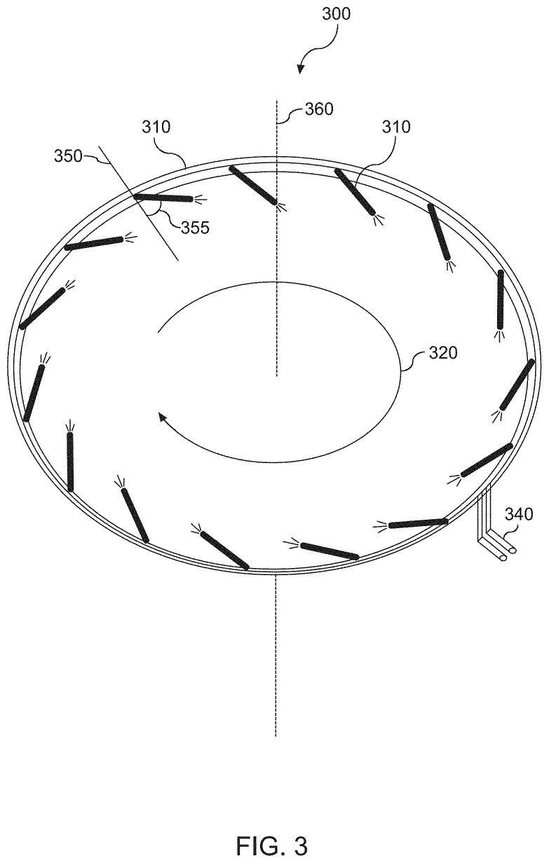

As shown in FIG. 1, according to example aspects of the present disclosure, the gas supply 190 delivers process gas into the processing chamber 102. The gas supply 190 is integrated with a side wall of the processing chamber 102. 0. The gas supply 190 includes multiple gas injectors 122 with feed gas ports. Each of the injectors can be angled relative to a direction parallel to a radius of the workpiece 106 to produce a rotational gas flow relative to a direction perpendicular to a center of the workpiece 106. In some embodiments (not shown in FIG. 1), the gas supply 190 can include one or more gas manifolds. Each gas manifold can be integrated with the processing chamber shields and/or liners 102. Each gas manifold can be parallel with the workpiece 106. Distances between a gas manifold and the workpiece 106 can be determined through calculations and/or various process test results. Each gas manifold can include one or more gas injectors 122 to deliver a gas flow around or toward a periphery of the workpiece 106. As one example, the injectors 122 can be angled in a clockwise or counter-clockwise direction to produce a clockwise or counter-clockwise gas flow relative to a direction perpendicular to a center of the workpiece 106. An angle between each injector and the direction parallel to the radius of the workpiece 106 can be no more than about 60 degrees, such as in the range of 15 degrees to about 45 degrees. In some embodiments, at least one injector of a gas manifold can be angled upward or downward to a workpiece. In some embodiments, the injectors 122 of a gas manifold can be in a diagonal direction toward to workpiece plane. Examples are further described in FIGS. 2 and 3.

In some embodiments (not shown in FIG. 1), at least an inlet port can be used for a circular gas manifold. For instance, two inlets can be used to flow a gas into the gas manifold. The two inlet ports can be configured close each other so that a small size of tee adapter/fitting can be used to deliver the gas from a single delivery line. Inside the gas manifold, gas particles from each inlet port can be collided or pushed away from each other. As a result, the two-port design can provide a better gas distribution for the injectors than a single gas port design. Examples are further described in FIGS. 2 and 3.

FIG. 2 depicts an example gas supply 200 according to example embodiments of the present disclosure. The gas supply 200 can be one of embodiments of the gas supply 190 shown in FIG. 1. The gas supply 200 includes a gas manifold 210. The gas manifold 210 includes a set of gas injectors 220 (e.g., about 15 gas injectors). The injectors 220 are arranged to aim at an edge of a workpiece (e.g., workpiece 106 shown in FIG. 1). Each of the injectors 220 is angled relative to a direction 250 parallel to a radius of the workpiece. For instance, an angle 255 between an injector 220 and the direction 250 parallel to the radius of the workpiece can be no more than about 60 degrees, such as in the range of 15 degrees to about 45 degrees. As shown in FIG. 2, the injectors 220 are angled in a counter-clockwise direction to produce a counter-clockwise gas flow 230 relative to a direction 260 perpendicular to a center of the workpiece. In some embodiments (not shown in FIG. 2), one or more of the injectors 220 can be angled upward or downward to the workpiece to produce the counter-clockwise gas flow 230. In some embodiments (not shown in FIG. 2), the injectors 220 can be in a diagonal direction toward to the workpiece. This can become a way to adjust or fine tune a gas flow concentration near an edge of a workpiece.

As shown in FIG. 2, the gas manifold 210 includes two inlets 240. The two inlets 240 are used to flow a gas into the gas manifold 210. The two inlet ports 240 are close each other so that a small size of tee adapter/fitting can be used to deliver the gas from a single delivery line. Inside the gas manifold, gas particles from each inlet port can be collided or pushed away from each other. As a result, the two-port design can provide a better gas distribution for the injectors 220.

FIG. 3 depicts an example gas supply 300 according to example embodiments of the present disclosure. The gas supply 300 can be one of embodiments of the gas supply 190 shown in FIG. 1. The gas supply 300 includes a gas manifold 310. The gas manifold 310 includes a set of gas injectors 320 (e.g., about 15 gas injectors). The injectors 320 are arranged to aim at an edge of a workpiece (e.g., workpiece 106 shown in FIG. 1). Each of the injectors 320 is angled relative to a direction 350 parallel to a radius of the workpiece. For instance, an angle 355 between an injector 320 and the direction 350 parallel to the radius of the workpiece can be no more than about 60 degrees, such as in the range of 15 degrees to about 45 degrees. As shown in FIG. 3, the injectors 320 are angled in a clockwise direction to produce a clockwise gas flow 330 relative to a direction 360 perpendicular to a center of the workpiece. In some embodiments (not shown in FIG. 3), one or more of the injectors 320 can be angled upward or downward to the workpiece to produce the clockwise gas flow 330. In some embodiments (not shown in FIG. 3), the injectors 320 can be in a diagonal direction toward to the workpiece. This can become a way to adjust or fine tune a gas flow concentration near an edge of a workpiece.

As shown in FIG. 3, the gas manifold 310 includes two inlets 340. The two inlets 340 are used to flow a gas into the gas manifold 310. The two inlet ports 340 are close each other so that a small size of tee adapter/fitting can be used to deliver the gas from a single delivery line. Inside the gas manifold, gas particles from each inlet port can be collided or pushed away from each other. As a result, the two-port design can provide a better gas distribution for the injectors 320.

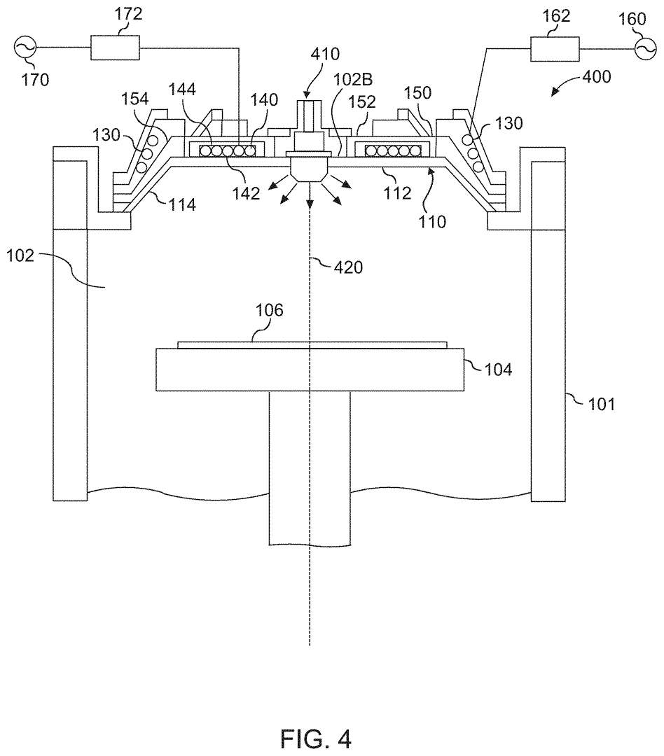

FIG. 4 depicts an example plasma processing apparatus 400 according to example embodiments of the present disclosure. The plasma processing apparatus 400 is similar to the plasma processing apparatus 100 of FIG. 1.

More particularly, the plasma processing apparatus 400 includes a processing chamber defining an interior space 102. A pedestal or workpiece holder 104 is used to support a workpiece 106, such as a semiconductor wafer, within the interior space 102. A dielectric window 110 is located above the workpiece holder 104. The dielectric window 110 includes a relatively flat central portion 112 and an angled peripheral portion 114. The dielectric window 110 includes a space in the central portion 112 for a gas supply 410 to feed process gas into the interior space 102.

The apparatus 100 further includes a plurality of inductive elements, such as primary inductive element 130 and secondary inductive element 140, for generating an inductive plasma in the interior space 102. The inductive elements 130, 140 can include a coil or antenna element that when supplied with RF power, induces a plasma in the process gas in the interior space 102 of plasma processing apparatus 100. For instance, a first RF generator 160 can be configured to provide electromagnetic energy through a matching network 162 to the primary inductive element 130. A second RF generator 170 can be configured to provide electromagnetic energy through a matching network 172 to the secondary inductive element 140.

The apparatus 100 can include a metal shield portion 152 disposed around the secondary inductive element 140. The metal shield portion 152 separates the primary inductive element 130 and the secondary inductive element 140 to reduce cross-talk between the inductive elements 130, 140. The apparatus 100 can further include a Faraday shield 154 disposed between the primary inductive element 130 and the dielectric window 130. Faraday shield 154 can be a slotted metal shield that reduces capacitive coupling between the primary inductive element 154 and the processing chamber 102. As illustrated, Faraday shield 154 can fit over the angled portion of the dielectric shield 110.

In a particular embodiment, metal shield 152 and Faraday shield 154 can form a unitary body 150 for ease of manufacturing and other purposes. The multi-turn coil of the primary inductive element 130 can be located adjacent the Faraday shield portion 154 of the unitary body metal shield/Faraday shield 150. The secondary inductive element 140 can be located proximate the metal shield portion 152 of metal shield/Faraday shield unitary body 150, such as between the metal shield portion 152 and the dielectric window 110.

The arrangement of the primary inductive element 130 and the secondary inductive element 140 on opposite sides of the metal shield 152 allows the primary inductive element 130 and secondary inductive element 140 to have distinct structural configurations and to perform different functions. For instance, the primary inductive element 130 can include a multi-turn coil located adjacent a peripheral portion of the process chamber. The primary inductive element 130 can be used for basic plasma generation and reliable start during the inherently transient ignition stage. The primary inductive element 130 can be coupled to a powerful RF generator and expensive auto-tuning matching network and can be operated at an increased RF frequency, such as at about 13.56 MHz.

The secondary inductive element 140 can be used for corrective and supportive functions and for improving the stability of the plasma during steady state operation. Since the secondary inductive element 140 can be used primarily for corrective and supportive functions and improving stability of the plasma during steady state operation, the secondary inductive element 140 does not have to be coupled to as powerful an RF generator as the first inductive element 130 and can be designed differently and cost effectively to overcome the difficulties associated with previous designs. In some instances, the secondary inductive element 140 can also be operated at a lower frequency, such as at about 2 MHz, allowing the secondary inductive element 140 to be very compact and to fit in a limited space on top of the dielectric window.

The primary inductive element 130 and the secondary inductive element 140 can be operated at different frequencies. The frequencies can be sufficiently different to reduce cross-talk between the primary inductive element 130 and the secondary inductive element 140. Due to the different frequencies that can be applied to the primary inductive element 130 and the secondary inductive element 140, there is reduced interference between the inductive elements 130, 140. More particularly, the only interaction in the plasma between the inductive elements 130, 140 is through plasma density. Accordingly, there is no need for phase synchronization between the RF generator 160 coupled to the primary inductive element 130 and the RF generator 170 coupled to the secondary inductive element 140. Power control is independent between the inductive elements. Additionally, since the inductive elements 130, 140 are operating at distinctly different frequencies, it is practical to use frequency tuning of the RF generators 160, 170 for matching the power delivery into the plasma, greatly simplifying the design and cost of any additional matching networks.

For instance (not shown in FIG. 4), the second inductive element 140 can include a planar coil and a magnetic flux concentrator. The magnetic flux concentrator can be made from a ferrite material. Use of a magnetic flux concentrator with a proper coil gives high plasma coupling and good energy transfer efficiency of the secondary inductive element 140, and significantly reduces its coupling to the metal shield 150. Use of a lower frequency, such as about 2 MHz, on the secondary inductive element 140 increases the skin layer, which also improves plasma heating efficiency.

In some embodiments, the different inductive elements 130 and 140 can carry different functions. Specifically, only the primary inductive element 130 has to carry out the most vital function of the plasma generation during ignition and providing enough priming for the secondary inductive element 140. This primary inductive element 130 can participate in the operation of the inductively coupled plasma (ICP) tool and should have coupling to both plasma and the grounded shield to stabilize plasma potential. The Faraday shield 154 associated with the first inductive element 130 can avoid window sputtering and can be used to supply the coupling to the ground.

As shown in FIG. 4, according to example aspects of the present disclosure, the gas supply 410 is located in a ceiling of the processing chamber 102 (e.g., on a top dome of the processing chamber 102). The gas supply 410 can include one or more gas injectors (not shown in FIG. 4). The injectors can be located at a center and/or one or more edges of the gas supply 410. The injectors can be arranged in an azimuthal symmetric gas injection pattern relative to a direction 420 perpendicular to a center of the workpiece 106. For instance, each of the injectors can be angled relative to a direction parallel to a radius of the workpiece 106 to produce a rotational gas flow relative to the direction 420. As one example, the injectors can be angled in a clockwise or counter-clockwise direction to produce a clockwise or counter-clockwise gas flow relative to the direction 420. An angle between each injector and the direction parallel to the radius of the workpiece can be no more than about 60 degrees, such as in the range of 15 degrees to about 45 degrees. In some embodiments, at least one injector can be angled upward or downward to the workpiece 106.

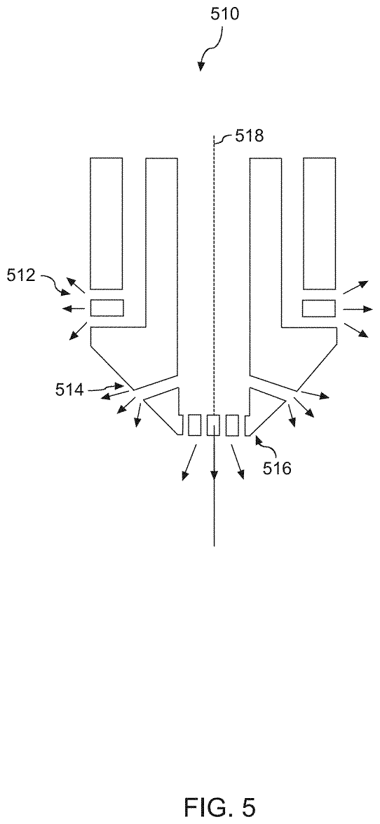

FIG. 5 depicts an example gas supply 510 according to example embodiments of the present disclosure. The gas supply 510 can be one of embodiments of the gas supply 420 shown in FIG. 4. FIG. 5 shows an axial cross-section view. As shown in the axial cross-section view, the gas supply 510 includes edge gas injectors 512, and center gas injectors 514 and 516. The edge gas injectors 512 can produce a rotational gas flow relative to a direction perpendicular to a center of a workpiece (e.g., workpiece 106 in FIG. 4). The center gas injectors 514 and 516 can produce a gas flow towards the center of the workpiece. In some embodiments (not shown in FIG. 5), the edge gas injectors 512 can be arranged in a counter-clockwise direction. In some embodiments (not shown in FIG. 5), the edge injectors 512 can be arranged in a clockwise direction. In some embodiments (not shown in FIG. 5), one or more of the injectors 512 can be angled upward or downward to the workpiece to produce the counter-clockwise gas flow 528 or the clockwise gas flow 538.

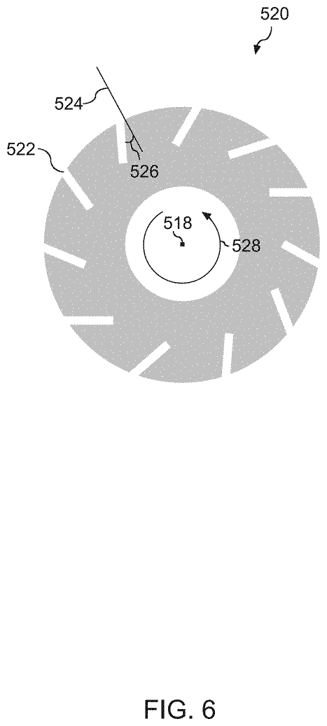

FIG. 6 depicts an example cross-section view 520 of edge gas injectors according to example embodiments of the present disclosure. the edge gas injectors 512 can be arranged in a counter-clockwise direction. As shown in the cross-section view 520, edge gas injectors 522 can be one embodiment of the edge gas injectors 512. Each of edge gas injectors 512 is angled relative to a direction 524 parallel to a radius of the workpiece. For instance, an angle 526 between an injector 522 and the direction 524 can be no more than about 60 degrees, such as in the range of 15 degrees to about 45 degrees. The edge gas injectors 522 are angled in a counter-clockwise direction to produce a counter-clockwise gas flow 528 relative to a direction 518 (also shown in FIG. 5) perpendicular to a center of the workpiece.

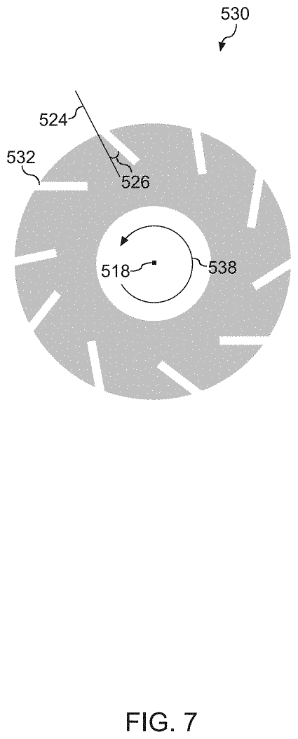

FIG. 7 depicts an example cross-section view 530 of edge gas injectors according to example embodiments of the present disclosure. the edge injectors 512 can be arranged in a clockwise direction. As shown in the cross-section view 530, edge gas injectors 532 can be one embodiment of the edge gas injectors 512. Each of edge gas injectors 532 is angled relative to a direction 524 parallel to a radius of the workpiece. For instance, an angle 526 between an injector 532 and the direction 524 can be no more than about 60 degrees, such as in the range of 15 degrees to about 45 degrees. The edge gas injectors 532 are angled in a clockwise direction to produce a clockwise gas flow 538 relative to the direction 518.

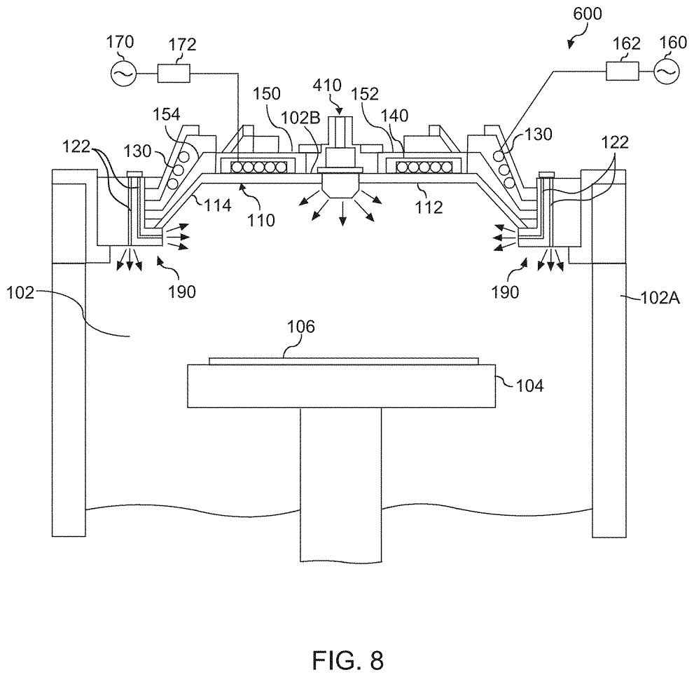

FIG. 8 depicts an example plasma processing apparatus 600 according to example embodiments of the present disclosure. The plasma processing apparatus 600 is similar to the plasma processing apparatus 100 of FIG. 1 and the apparatus 400 of FIG. 4.

More particularly, the plasma processing apparatus 400 includes a processing chamber defining an interior space 102. A pedestal or workpiece holder 104 is used to support a workpiece 106, such as a semiconductor wafer, within the interior space 102. A dielectric window 110 is located above the workpiece holder 104. The dielectric window 110 includes a relatively flat central portion 112 and an angled peripheral portion 114. The dielectric window 110 includes a space in the central portion 112 for a gas supply 410 to feed process gas into the interior space 102.

The apparatus 100 further includes a plurality of inductive elements, such as primary inductive element 130 and secondary inductive element 140, for generating an inductive plasma in the interior space 102. The inductive elements 130, 140 can include a coil or antenna element that when supplied with RF power, induces a plasma in the process gas in the interior space 102 of plasma processing apparatus 100. For instance, a first RF generator 160 can be configured to provide electromagnetic energy through a matching network 162 to the primary inductive element 130. A second RF generator 170 can be configured to provide electromagnetic energy through a matching network 172 to the secondary inductive element 140. The gas supply 190 is integrated with a side wall of the processing chamber 102.

The apparatus 100 can include a metal shield portion 152 disposed around the secondary inductive element 140. The metal shield portion 152 separates the primary inductive element 130 and the secondary inductive element 140 to reduce cross-talk between the inductive elements 130, 140. The apparatus 100 can further include a Faraday shield 154 disposed between the primary inductive element 130 and the dielectric window 130. Faraday shield 154 can be a slotted metal shield that reduces capacitive coupling between the primary inductive element 154 and the processing chamber 102. As illustrated, Faraday shield 154 can fit over the angled portion of the dielectric shield 110.

In a particular embodiment, metal shield 152 and Faraday shield 154 can form a unitary body 150 for ease of manufacturing and other purposes. The multi-turn coil of the primary inductive element 130 can be located adjacent the Faraday shield portion 154 of the unitary body metal shield/Faraday shield 150. The secondary inductive element 140 can be located proximate the metal shield portion 152 of metal shield/Faraday shield unitary body 150, such as between the metal shield portion 152 and the dielectric window 110.

The arrangement of the primary inductive element 130 and the secondary inductive element 140 on opposite sides of the metal shield 152 allows the primary inductive element 130 and secondary inductive element 140 to have distinct structural configurations and to perform different functions. For instance, the primary inductive element 130 can include a multi-turn coil located adjacent a peripheral portion of the process chamber. The primary inductive element 130 can be used for basic plasma generation and reliable start during the inherently transient ignition stage. The primary inductive element 130 can be coupled to a powerful RF generator and expensive auto-tuning matching network and can be operated at an increased RF frequency, such as at about 13.56 MHz.

The secondary inductive element 140 can be used for corrective and supportive functions and for improving the stability of the plasma during steady state operation. Since the secondary inductive element 140 can be used primarily for corrective and supportive functions and improving stability of the plasma during steady state operation, the secondary inductive element 140 does not have to be coupled to as powerful an RF generator as the first inductive element 130 and can be designed differently and cost effectively to overcome the difficulties associated with previous designs. In some instances, the secondary inductive element 140 can also be operated at a lower frequency, such as at about 2 MHz, allowing the secondary inductive element 140 to be very compact and to fit in a limited space on top of the dielectric window.

The primary inductive element 130 and the secondary inductive element 140 can be operated at different frequencies. The frequencies can be sufficiently different to reduce cross-talk between the primary inductive element 130 and the secondary inductive element 140. Due to the different frequencies that can be applied to the primary inductive element 130 and the secondary inductive element 140, there is reduced interference between the inductive elements 130, 140. More particularly, the only interaction in the plasma between the inductive elements 130, 140 is through plasma density. Accordingly, there is no need for phase synchronization between the RF generator 160 coupled to the primary inductive element 130 and the RF generator 170 coupled to the secondary inductive element 140. Power control is independent between the inductive elements. Additionally, since the inductive elements 130, 140 are operating at distinctly different frequencies, it is practical to use frequency tuning of the RF generators 160, 170 for matching the power delivery into the plasma, greatly simplifying the design and cost of any additional matching networks.

For instance (not shown in FIG. 8), the second inductive element 140 can include a planar coil and a magnetic flux concentrator. The magnetic flux concentrator can be made from a ferrite material. Use of a magnetic flux concentrator with a proper coil gives high plasma coupling and good energy transfer efficiency of the secondary inductive element 140, and significantly reduces its coupling to the metal shield 150. Use of a lower frequency, such as about 2 MHz, on the secondary inductive element 140 increases the skin layer, which also improves plasma heating efficiency.

In some embodiments, the different inductive elements 130 and 140 can carry different functions. Specifically, only the primary inductive element 130 has to carry out the most vital function of the plasma generation during ignition and providing enough priming for the secondary inductive element 140. This primary inductive element 130 can participate in the operation of the inductively coupled plasma (ICP) tool and should have coupling to both plasma and the grounded shield to stabilize plasma potential. The Faraday shield 154 associated with the first inductive element 130 can avoid window sputtering and can be used to supply the coupling to the ground

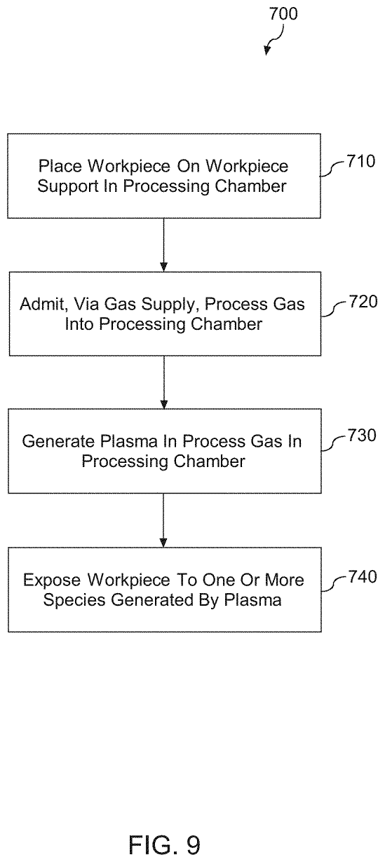

FIG. 9 depicts a flow diagram of an example method (700) according to example embodiments of the present disclosure. The method (700) will be discussed with reference to the plasma processing apparatus 100 of FIG. 1 by way of example. The method (700) can be implemented in any suitable plasma processing apparatus. FIG. 9 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (710), the method can include placing a workpiece on a workpiece support in a processing chamber. For instance, a workpiece 106 can be placed in a workpiece support 104 in a processing chamber 102.

At (720), the method can include admitting, via a gas supply, a process gas into the processing chamber. For instance, a gas supply 190 integrated with a side wall of a processing chamber 102, and/or a gas supply 410 on a ceiling of the processing 102 can admit a process gas into the processing chamber 102. The gas supply 190 or the gas supply 410 can include one or more injectors. Each injector can be angled (e.g., in a clockwise direction or a counter-clockwise direction) relative to a direction parallel to a radius of the workpiece 106. Such arrangement of the injectors can produce a rotational gas flow (e.g., a clockwise gas flow or a counter-clockwise gas flow) relative to a direction perpendicular to a center of the workpiece 106.

At (730), the method can include generating a plasma in the process gas in the processing chamber. For instance, a primary inductive element 130, and/or a secondary inductive element 140 can generate a plasma in the process gas in the processing chamber 102.

At (740), the method can include exposing the workpiece to one or more species generated by the plasma. For instance, the workpiece 106 can be exposed to one or more species generated by the plasma.

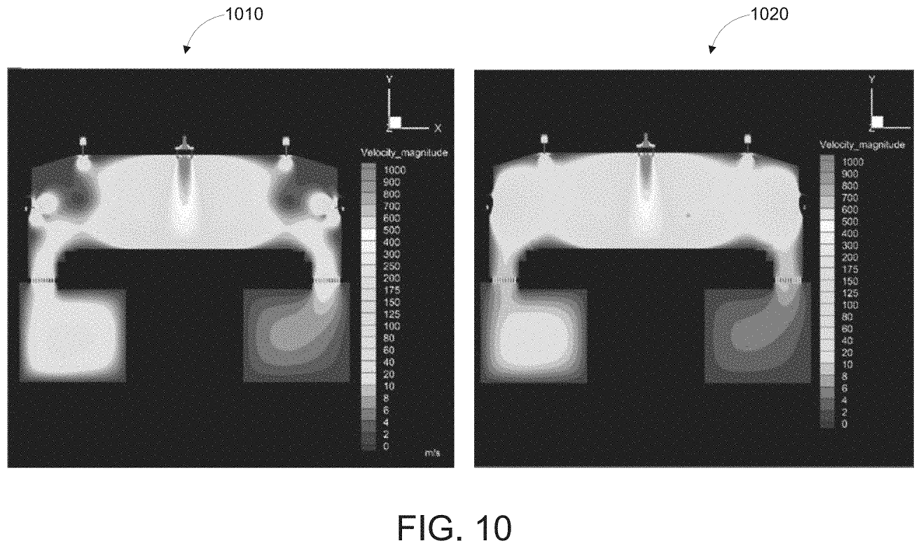

FIG. 10 depicts an example gas velocity comparison between a gas supply 1010 and an example gas supply 1020 according to example embodiments of the present disclosure. As can be seen in FIG. 10, the gas supply 1010 includes center gas injectors, edge gas injectors and side gas injectors. The edge gas injectors and/or side gas injectors are arranged in a direction parallel to a radius of the workpiece. The example gas supply 1020 according to example embodiments of the present disclosure includes center gas injectors, edge gas injectors and side gas injectors. The edge gas injectors and/or side gas injectors are angled relative to a direction parallel to a radius of the workpiece to produce a rotational gas flow relative to a direction perpendicular to a center of the workpiece. As can be seen from FIG. 10, the example gas supply 1020 can reduce a stagnant gas flow area.

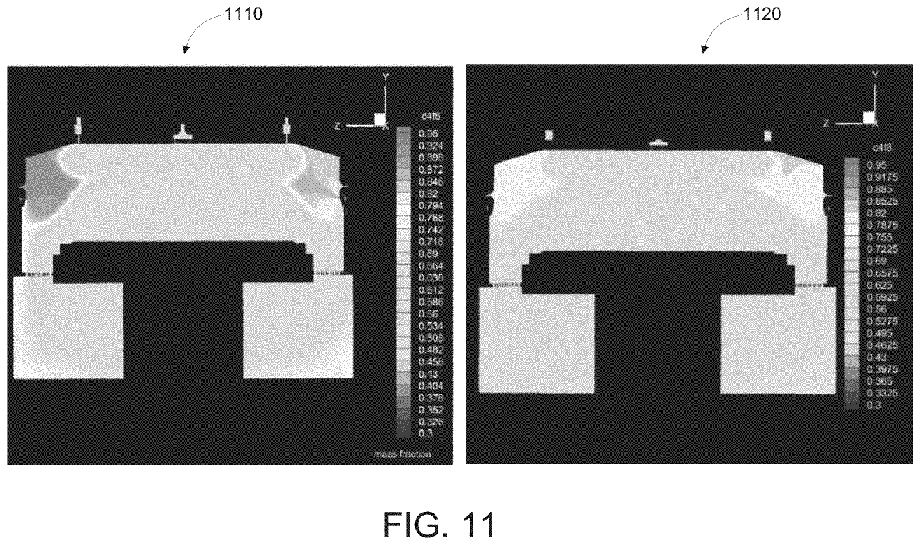

FIG. 11 depicts an example mass fraction comparison between a gas supply 1110 and an example gas supply 1120 according to example embodiments of the present disclosure. The gas supply 1110 includes standard side gas injectors toward a center line of a workpiece. The example gas supply 1120 includes side gas injectors angled relative to a direction parallel to a radius of the workpiece to produce a rotational gas flow relative to a direction perpendicular to a center of the workpiece. As can be seen from FIG. 11, the example gas supply 1120 can reduce mass-fraction difference within the processing chamber.

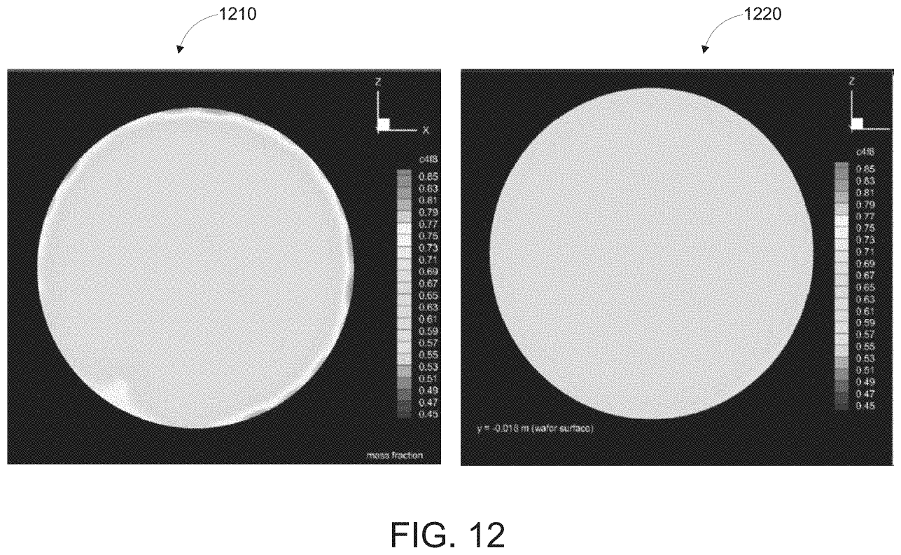

FIG. 12 depicts an example comparison of mass fraction on workpiece surface distribution between a gas supply and an example gas supply according to example embodiments of the present disclosure. The gas supply associated with workpiece 1210 includes standard side gas injectors toward a center line of a workpiece. The example gas supply associated with workpiece 1220 includes side gas injectors angled relative to a direction parallel to a radius of the workpiece to produce a rotational gas flow relative to a direction perpendicular to a center of the workpiece. As shown from FIG. 12, the example gas supply associated with workpiece 1220 can reduce mass-fraction non-uniformity at a surface of the workpiece 1210.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A plasma processing apparatus, comprising:
a processing chamber having a workpiece support, the workpiece support configured to support a workpiece during plasma processing,
an inductively coupled plasma source configured to induce a plasma in a process gas in the processing chamber;
a gas supply configured to deliver the process gas to the processing chamber, the gas supply comprising one or more injectors, wherein each of the one or more injectors is at an angle in a plane parallel to a workpiece plane relative to a direction parallel to a respective radius of the workpiece to produce a rotational gas flow relative to a direction perpendicular to a center of the workpiece,
wherein at least one of the one or more injectors is integrated with a side wall of the processing chamber, and
wherein the gas supply comprises at least one gas manifold, the at least one gas manifold comprising the one or more injectors.

2. The plasma processing apparatus of claim 1, wherein another of the one or more injectors is located in a ceiling of the processing chamber such that the gas supply delivers the process gas into the processing chamber from a top of the processing chamber.

3. The plasma processing apparatus of claim 1, wherein each of the one or more injectors is integrated with the side wall of the processing chamber.

4. The plasma processing apparatus of claim 1, wherein the at least one of the one or more injectors integrated with the side wall of the processing chamber delivers the process gas at a downstream location from the inductively coupled plasma source.

5. The plasma processing apparatus of claim 1, wherein at least one injector of the one or more injectors is angled upward relative to the workpiece.

6. (canceled)

7. The plasma processing apparatus of claim 1, wherein the one or more injectors are angled in a clockwise direction to produce a clockwise gas flow relative to the direction perpendicular to the center of the workpiece.

8. The plasma processing apparatus of claim 7, wherein the angle in the plane parallel to the workpiece plane between each injector of the one or more injectors and the direction parallel to the respective radius of the workpiece is no more than about 60 degrees.

9. The plasma processing apparatus of claim 1, wherein the one or more injectors are angled in a counter-clockwise direction to produce a counter-clockwise gas flow relative to the direction perpendicular to the center of the workpiece.

10. The plasma processing apparatus of claim 9, wherein the angle in the plane parallel to the workpiece plane between each injector of the one or more injectors and the direction parallel to the respective radius of the workpiece is no more than about 60 degrees.

11. A method of processing a workpiece, comprising:
placing the workpiece on a workpiece support in a processing chamber;
admitting, via a gas supply, a process gas into the processing chamber;
generating a plasma in the process gas in the processing chamber;
exposing the workpiece to one or more species generated by the plasma;
wherein the gas supply comprises one or more injectors, each injector of the one or more injectors is angled relative to a direction parallel to a radius of the workpiece to produce a rotational gas flow relative to a direction perpendicular to a center of the workpiece.

12. The method of claim 11, wherein the gas supply is integrated with a ceiling of the processing chamber such that the gas supply delivers the process gas into the processing chamber from a top of the processing chamber.

13. The method of claim 11, wherein the gas supply is integrated with a side wall of the processing chamber.

14. The method of claim 13, wherein at least one injector of the one or more injectors delivers the process gas at a downstream location from a plasma source inducing the plasma.

15. The method of claim 11, wherein at least one injector of the one or more injectors is angled upward relative to the workpiece.

16. The method of claim 11, wherein the gas supply comprises at least one gas manifold, the at least one gas manifold comprising the one or more injectors.

17. The method of claim 11, wherein the one or more injectors are angled in a clockwise direction to produce a clockwise gas flow relative to the direction perpendicular to the center of the workpiece.

18. The method of claim 11, wherein an angle between each injector of the one or more injectors and the direction parallel to the radius of the workpiece is no more than about 60 degrees.

19. The method of claim 11, wherein the one or more injectors are angled in a counter-clockwise direction to produce a counter-clockwise gas flow relative to the direction perpendicular to the center of the workpiece.

20. The method of claim 11, wherein an angle between each injector of the one or more injectors and the direction parallel to the radius of the workpiece is no more than about 60 degrees.
